(19) United States
(12) Patent Application Publication
(10) Pub. No.: US 2006/0114074 A1
(43) Pub. Date: Jun. 1, 2006

(54) Semiconductor integrated circuit for communication incorporating oscillator, communication system, and method for manufacturing the semiconductor integrated circuit

(76) Inventors: Toshiki Matsui, Takasaki (JP); Masumi Kasahara, Takasaki (JP); Norio Hayashi, Tamamura (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/289,470

(22) Filed: Nov. 30, 2005

(30) Foreign Application Priority Data
Dec. 1, 2004 (JP) 2004-348046

(51) Int. Cl. H03B 5/12

(52) U.S. Cl. 331/177 V

(57) ABSTRACT

A semiconductor integrated circuit for communication has a reference oscillator with high frequency control accuracy. The oscillator has a capacitive load circuit including a plurality of fixed capacitance elements, a plurality of variable capacitance elements, and switch elements connected to the capacitance elements, and is configured such that it can oscillate at a frequency corresponding to a synthesized capacitance value of the fixed capacitance elements, variable capacitance elements, and external oscillation elements. Through a control circuit that can generate a signal for controlling the switch elements, a combination of the variable capacitance element and the fixed capacitance element can be selected, in which the slopes of the characteristics of the frequency to control voltage are equalized, and intervals between the respective characteristic lines are equalized by the synthesized capacitance value of the capacitive load circuit and the oscillation elements.

### CROSS-REFERENCE TO RELATED APPLICATION

The present application claims priority from Japanese patent application No 2004-348046 filed on Dec. 1, 2004, the content of which is hereby incorporated by reference into this application.

### BACKGROUND OF THE INVENTION

1. Field of the Invention

The present invention relates to a technique effective for applying to a semiconductor integrated circuit incorporating a voltage controlled oscillator (VCO: Voltage Controlled Oscillator) and method for manufacturing the circuit; and for example, relates to a technique effective for applying to a semiconductor integrated circuit for communication, which configures a wireless communication system such as mobile phone, and incorporates an oscillator for generating a reference signal to be necessary for a PLL circuit for generating a high-frequency oscillation signal used for modulation/demodulation of transmission/reception signals.

2. Description of Related Art

In the wireless communication system such as mobile phone, a high frequency semiconductor integrated circuit (hereinafter, referred to as high-frequency IC) is used, which has the PLL circuit including an oscillator for generating a local oscillation signal having a predetermined frequency which is synthesized with a transmission signal or a reception signal for modulation/demodulation to perform modulation of the transmission signal or demodulation of the reception signal.

The PLL circuit, which has the voltage controlled oscillator, compares a phase of a signal as a reference (reference signal) to a phase of a feedback signal of the voltage controlled oscillator, and controls the voltage controlled oscillator such that phase difference between them is zero, and reception frequency or transmission frequency is determined according to the oscillation frequency of the voltage controlled oscillator. Therefore, in a communication system such as GSM (Global System for Mobile Communication) type, the frequency generated by the voltage controlled oscillator is required to have extremely excellent accuracy in frequency, for example, variation ratio of ±23 ppm with respect to the reference signal.

In a high-frequency IC incorporating an oscillator (hereinafter, referred to as reference oscillator) for generating a reference signal, control called AFC (Automatic Frequency Control) for matching of frequency of the generated reference signal with the reference clock from a base station is performed.

On the other hand, since the mobile phone is largely demanded to be reduced in size and weight, decrease in number and size of external components is important, naturally in addition to decrease in chip size of IC. In the conventional high frequency IC used for mobile phone, a voltage controlled oscillator having a variable capacitance element for frequency adjustment comprising an external quartz resonator, varactor diode and the like as the reference oscillator has been often used.

Patent literature 1: JP-A-2004-48589.

### SUMMARY OF THE INVENTION

In such a reference oscillator, since the variable capacitance element is indispensable for AFC control and not omissible, an oscillation element that is not highly accurate but inexpensive is used for cost reduction, and an accompanying variation in frequency is adjusted by the variable capacitance element. Thus, it has been considered that the variable capacitance element is used to perform the frequency control for AFC control and adjust frequency error due to a variation in manufacturing an oscillation element, enabling reduction in total cost. However, to achieve such control and adjustment, there is a problem that a wide frequency control range of the variable capacitance element, or a wide capacitance variation range of the variable capacitance element is necessary, which is hardly realized without using an external variable capacitance element like a monolithic element.

On the other hand, to achieve reduction in size and weight of the mobile phone, it is effective that the variable capacitance element of the reference oscillator is formed as an on-chip element to reduce the number of external elements like monolithic elements. Thus, a method was considered, wherein fixed capacitance elements were provided in addition to the variable capacitance element, and the number of fixed capacitance elements to be connected was changed by switches, and voltage applied to the variable capacitance element was continuously changed to change a total capacitance value, thereby desired oscillation frequency was obtained. The inventors initially considered that according to such a method, the reference oscillator including the frequency adjustment circuit having the variable capacitance element and the fixed capacitance elements was incorporated in a semiconductor chip, and only the oscillation element was formed as the external element, enabling reduction in size; and investigated on the method.

However, while such a reference oscillator can provide a desired range on a variable range of frequency, when the number of fixed capacitance elements to be connected is changed, as shown in FIG. 5, a slope of each of characteristics of frequency to control voltage, or sensitivity of oscillation frequency (hereinafter, referred to as control sensitivity) against control voltage is shifted, while the shift is slight. The inventors found that it caused disadvantages of a variation in frequency control range and reduction in accuracy of frequency control.

As the art similar to the invention, an invention described in patent literature 1 is given, however, in the related invention, the fixed capacitance element and the variable capacitance element are made in a pair, and the number of pairs to be connected is changed by a switch when frequency is changed, that is, the fixed capacitance element and the variable capacitance element are changed in a different way from the invention, and capacitance values of the fixed capacitance element and the variable capacitance element are set in a different way from the invention.

An object of the invention is to provide a semiconductor integrated circuit for communication (high frequency IC) incorporating a reference oscillator that is excellent in frequency control accuracy, and may have small number of external components and thus can be reduced in size.

Another object of the invention is to provide a semiconductor integrated circuit for communication (high frequency IC) incorporating the reference oscillator that is excellent in frequency control accuracy even if an inexpensive oscillation element is used, enabling cost reduction.

The described and other objects and novel features of the invention will be clarified according to description of the specification and accompanying drawings.

Summary of typical one in the inventions disclosed in the application is briefly described as follows.

That is, a semiconductor integrated circuit for communication (high frequency IC) incorporating an oscillator that has a capacitive load circuit including a plurality of fixed capacitance elements, a plurality of variable capacitance elements, and switch elements connected to the capacitance elements, and is configured such that it can oscillate at a frequency corresponding to a synthesized capacitance value of the fixed capacitance elements, variable capacitance elements, and external oscillation elements is given; wherein a control circuit that can generate a signal for controlling the switch elements such that a combination of the variable capacitance elements and the fixed capacitance elements can be selected, in which slopes of the characteristics of frequency to control voltage are equalized, and intervals between respective characteristic lines are equalized by the synthesized capacitance value of the capacitive load circuit and the oscillation elements.

According to the configuration, since the fixed capacitance elements are appropriately combined with the variable capacitance elements and connected thereto by the switches, the slopes of the characteristics of frequency to control voltage of the oscillator can be equalized, and accuracy of frequency control can be improved. Moreover, since the fixed capacitance elements and the variable capacitance elements can be formed in an on-chip manner, the number of external components may be reduced and thus size can be reduced, in addition, since frequency can be controlled at high accuracy over a wide range, even if the inexpensive oscillation element is used, cost reduction can be achieved.

Advantageous effects obtained by a typical one in the inventions disclosed in the application are briefly described as follows.

That is, according to the invention, the semiconductor integrated circuit for communication (high frequency IC) can be realized, which incorporates the reference oscillator that is excellent in accuracy of frequency control, and may have small number of external components, enabling size reduction, and has the frequency control accuracy which is still excellent even if the inexpensive oscillation element is used, enabling cost reduction.

### BRIEF DESCRIPTION OF THE DRAWINGS

FIG. 1 is an illustrative view showing an embodiment of a voltage controlled oscillator (VCO) according to the invention, and an example of a configuration of a relevant part of a high frequency IC using the oscillator as a reference signal generation source;

FIG. 2 is a circuit diagram showing an equivalent circuit of a quartz resonator;

FIG. 3 is a characteristic diagram showing a relation between control voltage V_{AFC} and a frequency range required for the oscillator of the embodiment;

FIG. 4 is a characteristic diagram showing a relation between control voltage V_{AFC} and a frequency range in the oscillator of the embodiment;

FIG. 5 is a characteristic diagram showing a relation between control voltage V_{AFC} and a frequency range in the conventional oscillator;

FIG. 6 is a characteristic diagram showing a relation between a total capacitance value C_{X} of a capacitive load circuit and a frequency variation X in the oscillator of the embodiment;

FIG. 7 is a cross section view showing a specific example of a varactor diode suitable for use in a variable capacitance element configuring the oscillator of the embodiment; and

FIG. 8 is a block diagram showing a semiconductor integrated circuit for communication (high frequency IC), using the oscillator of the embodiment and an example of a configuration of a wireless communication system using the circuit.

### DETAILED DESCRIPTION OF THE INVENTION

Next, an embodiment of the invention is described using drawings.

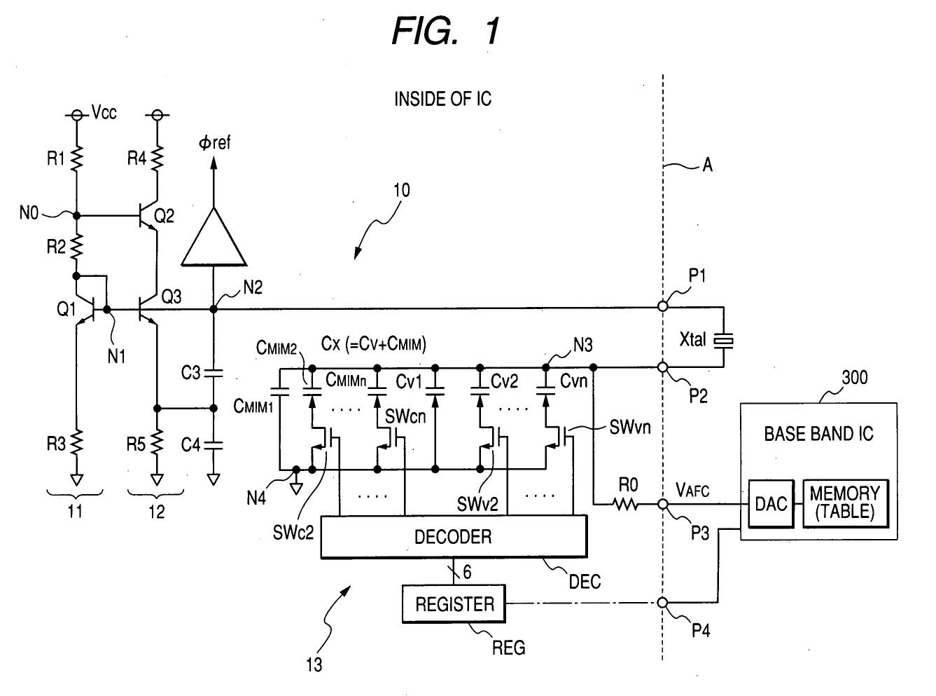

FIG. 1 shows an embodiment of a voltage controlled oscillator (VCO) according to the invention, and an example of a configuration of a relevant part of a high frequency IC using the oscillator as a reference signal generation source. In FIG. 1, a circuit shown at a left side with respect to a dashed line A is formed as a semiconductor integrated circuit on one semiconductor chip such as single crystal silicon.

The voltage controlled oscillator (VCO) 10 of the embodiment comprises resistors R1, R2 connected in series between a source voltage terminal Vcc and a ground point, a bias circuit 11 comprising a transistor Q1 and a resistor R3, a resistor R4 connected in series between the source voltage terminal Vcc and the ground point, an excitation circuit 12 comprising transistors Q2, Q3 and a resistor R5, a capacitance element C3 connected between a base and an emitter of the transistor Q3 of the excitation circuit, a capacitance element C4 connected between the emitter of the transistor Q3 and the ground point, and a capacitive load circuit 13 that has fixed capacitance elements C_{MIM1} to C_{MIMn}, and variable capacitance elements Cv1 to Cvn, and is adjustable in its capacitance value; and electric potential of a connection node N0 for the resistors R1 and R2 of the bias circuit 11 is applied to a base of the transistor Q2, and electric potential of a connection node N1 for the resistor R2 and a base terminal of the transistor Q1 is applied to a base of the transistor Q3.

A connection node N2 for one terminal of the capacitance element C3 and a base terminal of the transistor Q3 is connected to an outer terminal P1, one nodes N3 of common connection nodes for fixed capacitance elements C_{MIM1} to C_{MIMn} and variable capacitance elements Cv1 to Cvn of the capacitive load circuit 13 are connected to an outer terminal P2, and an external reference oscillation element, for example, a quartz resonator Xtal is connected between P1 and P2. Furthermore, the common connection nodes N3 are connected to an external terminal P3 via a resistor R0, and AFC control voltage V_{AFC} is applied to the external terminal P3 from a baseband circuit outside the chip. For example, MIM capacitance elements comprising metal films, which are formed such that they are opposed across an insulating film such as silicon nitride film on a semiconductor chip, are used for the fixed capacitance elements C_{MIM1} to C_{MIMn}, and for example, varactor diodes comprising a PN junction formed within a semiconductor chip are used for the variable capacitance elements Cv1 to Cvn.

The capacitive load circuit 13 comprises the fixed capacitance elements C_{MIM1} to C_{MIMn} and the variable capacitance elements Cv1 to Cvn, switch elements SWc2 to SWcn and SWv2 to SWvn comprising MOSFET provided in series to the fixed capacitance elements C_{MIM2} to C_{MIMn} and the variable capacitance elements Cv2 to Cvn of the elements, a register REG for holding control codes for the switch elements, and a decoder DEC that decodes the control codes set into the register REG to generate gate control signals for the switch elements SWc2 to SWcn and SWv2 to SWvn, wherein the other common connection nodes N4 for the fixed capacitance elements C_{MIM1} to C_{MIMn} and the variable capacitance elements Cv1 to Cvn are connected to the ground point.

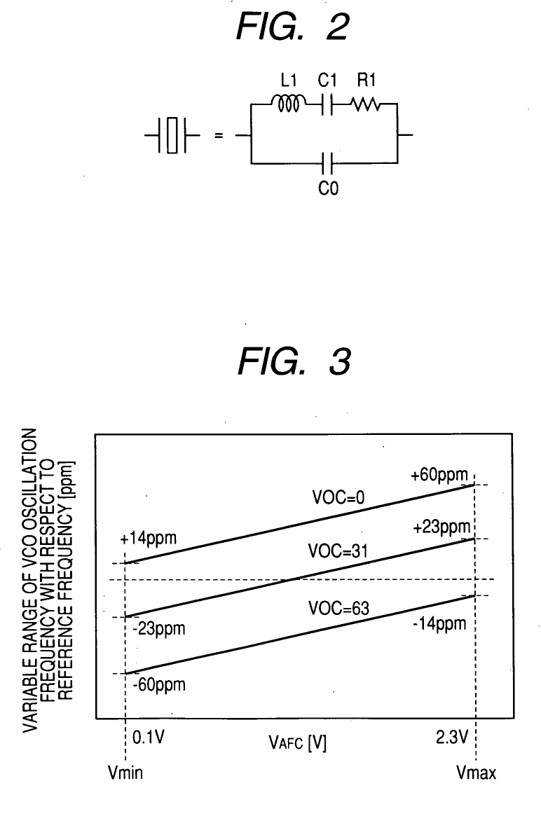

Next, a way of setting the capacitance value of each element of the variable capacitance elements Cv1 to Cvn and the fixed capacitance elements C_{MIM1} to C_{MIMn} and a way controlling each of the switch elements SWc2 to SWcn and SWv2 to SWvn are described. The quartz resonator Xtal is expressed by an equivalent circuit as shown in FIG. 2.

When frequency inherent to the quartz resonator, which is expressed by 2π√(LC1·C1) using an inductor L1 and a capacitance element C1 configuring the equivalent circuit, is replaced by fs, and total capacitance (C_{MIM} and Cv) of a capacitance array (the variable capacitance elements Cv1 to Cvn and the fixed capacitance elements C_{MIM1} to C_{MIMn}) in the oscillator of FIG. 1 is replaced by C_{X}, synthesized capacitance CL of the capacitance elements C3, C4 as load of the oscillator, C_{MIM1} to C_{MIMn}, and Cv1 to Cvn is expressed by CL=1/{(1/C3)+(1/C4)+(1/C_{X})}, and oscillation frequency f of the oscillator of FIG. 1 is expressed by the following equation (1).

$$f = fs \times ( 1 + \frac{1}{2 \times \frac{C0}{C1}} \times \frac{1}{1 \times \frac{CL}{C0}} ) \qquad ( 1 )$$

Here, when oscillation frequency f at any optional synthesized capacitance CL is expressed using deviation Δf [ppm] from the frequency fs inherent to the quartz resonator, the following equation (2) is obtained from the equation (1).

$$Δ f [ ppm ] = \frac{f - fs}{fs} = \frac{C1}{2 ( C0 + CL )} \qquad ( 2 )$$

Furthermore, when a central value of the synthesized capacitance CL of an actually used oscillator is replaced by CL_{center}, and oscillation frequency in that case is replaced by f_{center}, deviation of the oscillation frequency Δf_{center} is expressed by the following equation (3).

$$Δ fcenter = \frac{fcenter - fs}{fs} = \frac{C1}{2 ( C0 + CLcenter )} \qquad ( 3 )$$

A value CLx of synthesized capacitance CL necessary for changing oscillation frequency of the oscillator only by X [ppm] is given by equation (5) from the following equation (4).

$$\begin{matrix}\begin{matrix}X [ ppm ] = Δ fx - Δ fcenter \\ = \frac{C1}{2 ( C0 + CLx )} - \frac{C1}{2 ( C0 + CLcenter )}\end{matrix} & ( 4 ) \\ CLx [ p F ] = \frac{1}{\frac{2 X}{C1} + \frac{1}{( C0 + CLcenter )}} - C0 & ( 5 )\end{matrix}$$

Hereinafter, oscillation frequency of VCO is expressed using a variable ratio X [ppm] from the frequency fs inherent to the quartz resonator as a reference.

When the synthesized capacitance CLx is expressed using the total capacitance Cx of the capacitance array, it is expressed by CLx=1/{(1/C3)+(1/C4)+(1/Cx)}, therefore Cx is expressed by the following equation (6), which is changed as the following equation (7).

$$\begin{matrix}Cx = \frac{1}{\frac{1}{\frac{1}{\frac{2 X}{C1} + \frac{1}{C0 + CLcenter}} - C0} - ( \frac{1}{C3} + \frac{1}{C4} )} & ( 6 ) \\ Cx = \frac{\frac{( \frac{C1}{2} )}{{\{ 1 + C0 ( \frac{1}{C3} + \frac{1}{C4} ) \}}^{2}}}{X + ( \frac{C1}{2} ) \cdot ( \frac{1}{( C0 + CLcenter )} - \frac{( \frac{1}{C3} + \frac{1}{C4} )}{1 + C0 ( \frac{1}{C3} + \frac{1}{C4} )} )} - ( \frac{C0}{1 + C0 ( \frac{1}{C3} + \frac{1}{C4} )} ) & ( 7 )\end{matrix}$$

In the above equations, C0, C1, C3, C4 and CL_{center} can be used as constants determined depending on characteristics of the quartz resonator to be used and fixed capacitance in IC, and thus when the VCO is required to be oscillated at X [ppm], the total capacitance Cx of the variable capacitance elements Cv1 to Cvn and fixed capacitance elements C_{MIM1} to C_{MIMn} can be expressed as the following equation (8).

$$Cx = \frac{D}{X + E} + F \qquad ( 8 )$$

Herein, D, E, and F are expressed as follows.

$$D = \frac{( \frac{C1}{2} )}{{\{ 1 + C0 ( \frac{1}{C3} + \frac{1}{C4} ) \}}^{2}} \\ E = ( \frac{C1}{2} ) \{ \frac{1}{C0 + CLcenter} - \frac{( \frac{1}{C3} + \frac{1}{C4} )}{1 + C0 ( \frac{1}{C3} + \frac{1}{C4} )} \} \\ F = \frac{- C0}{1 + C0 ( \frac{1}{C3} + \frac{1}{C4} )} \qquad ( 9 )$$

Next, a value of the variable capacitance element Cv and a value of the fixed capacitance element C_{MIM} are obtained when they are required to be controlled in a range from X1 [ppm] to X2 [ppm] using control voltage V_{AFC} (minimum value Vₘᵢₙ and maximum value Vₘₐₓ). Since variations of capacitance Cx1 to Cx2 are equal to capacitance values of the variable capacitance element Cv when it varies at a control voltage V_{AFC}, the following equation (10) is obtained.

$$Cx1 - Cx2 = ( \frac{D}{{X}_{1} + E} + F ) - ( \frac{D}{{X}_{2} + E} + F ) = ( α - β ) Cv \qquad ( 10 )$$

In the equation (10), α is a ratio between a capacitance value of Cv when the minimum value Vₘᵢₙ of the control voltage V_{AFC} is applied and a capacitance value of Cv when 0V is applied, and β is a ratio between a capacitance value of Cv when the maximum value Vₘₐₓ of the control voltage V_{AFC} is applied, and a capacitance value of Cv when 0 V is applied. Since the value of the fixed capacitance element C_{MIM} is obtained by subtracting the capacitance value of the variable capacitance element Cv from the total capacitance value of the capacitance array, it is expressed by the following equation (11). One of the fixed capacitance elements C_{MIM1} to C_{MIMn} is an element having a minimum capacitance value necessary for obtaining a desired variable frequency range by the synthesized capacitance of the variable capacitance element Cv and the capacitance elements C3, C4; and others are formed as elements having capacitance values that provide differences with the minimum capacitance value.
Cx1−αCV=C_{MIM} (11)

Hereinafter, a specific example is described. It is assumed that capacitance C1 is 6.9 fF, capacitance C0 is 1.7 pF, inductance L1 is 2.4911 mH, and resistance R1 is 10 Ω in an equivalent circuit of FIG. 2 in the quartz resonator to be used; the central value CL_{center} of the synthesized capacitance CL is 9.5 pF; the capacitance array comprising the variable capacitance element Cv and the fixed capacitance element C_{MIM} is formed such that the total capacitance value Cx can be changed in 64 stages; a frequency range that can be changed by the control voltage V_{AFC} in one stage (hereinafter, referred to as band) is f_{center}±23 ppm; and a frequency range that can be changed by the capacitance array as a whole is f_{center}±60 ppm. These are diagrammatically represented as FIG. 3. In FIG. 3, VOC0, VOC31, and VOC63 are signs indicating respective bands. In FIG. 3, characteristics of bands VOC1 to VOC30 and VOC32 to VOC62 are omitted to be shown.

Both the capacitance C3 and the capacitance C4 as load of the oscillation are assumed to be 55 pF. The condition is substituted for the equation (9), thereby D=3.05998×10⁻¹⁵, E=0.18989×10⁻³, and F=−1.60103×10⁻¹² are obtained. The D, E, F and X are substituted for the equation (8), thereby the total capacitance Cx of the capacitance array can be determined. Then, the value of the variable capacitance element Cv and the value of the fixed capacitance element C_{MIM} can be determined from the determined value of Cx using the equations (10) and (11).

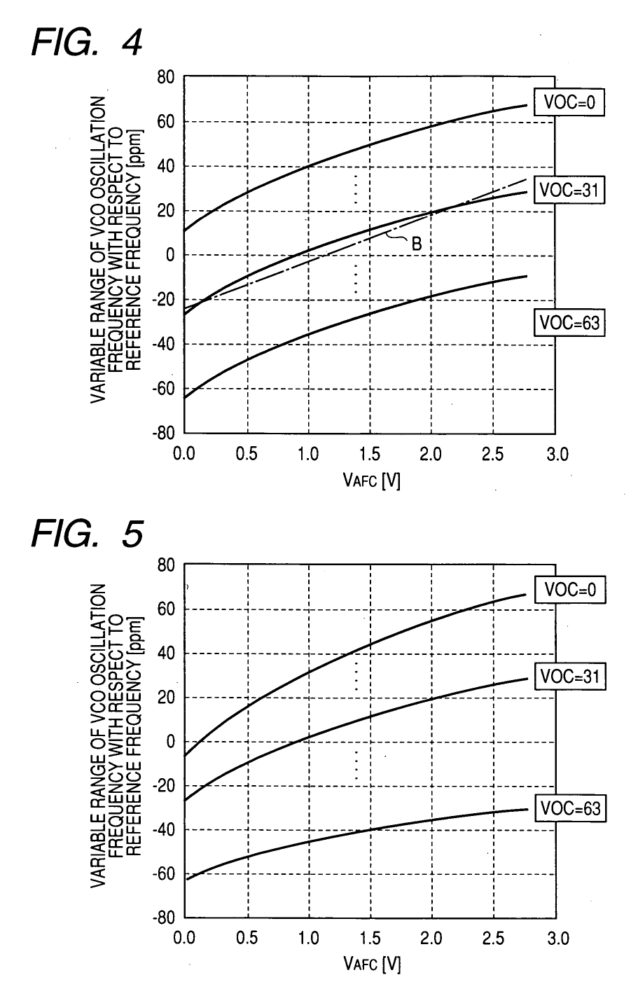

Therefore, the decoder DEC, which outputs signals for controlling the switch elements SWc2 to SWcn and SWv2 to SWvn is designed such that a combination of the variable capacitance element Cv and the fixed capacitance element C_{MIM} can be selected, in which slopes of the characteristics of control voltage to frequency in respective bands are equalized, and intervals between characteristic lines in respective bands are equalized as shown in FIG. 4. Alternatively, when the decoder is fixed, that is, a relation between input and output is constant, it is acceptable that codes for controlling the switch elements SWc2 to SWcn and SWv2 to SWvn have been prepared as a data table such that a combination of the variable capacitance element Cv and the fixed capacitance element C_{MIM} can be selected, in which slopes of the characteristics of control voltage to frequency in respective bands are equalized, and intervals between characteristic lines in respective bands are equalized, and the codes are stored in a nonvolatile memory such as flash memory in a circuit (baseband circuit in the system of FIG. 1) for controlling the oscillator.

If there is no variation in production, VOC31 can be selected because it is most similar to the characteristic required for the oscillator, however in actual products, the characteristic of control to frequency of the oscillator is shifted from a designed value due to a variation in elements configuring the oscillator or a characteristic of the quartz resonator to be used and a variation of the characteristic. Thus, in the embodiment, the code is set from the baseband circuit into the register REG of FIG. 1 such that one of bands that is most similar to the characteristic of the designed value is selected from 64 characteristics indicated by VOC0 to VOC63 of FIG. 4 for each high frequency IC to be used.

Accordingly, accuracy in frequency control of the oscillator can be improved. While the number of bands was assumed to be 64 in the embodiment, it is not limited to this. As the number of bands is increased, accuracy is improved but circuit scale becomes large, therefore an appropriate number of bands can be determined according to balance between chip size and required accuracy.

The varactor diodes as the variable capacitance elements Cv1 to Cvn are elements using a phenomenon that thickness of a depletion layer, which is produced upon application of reverse bias to the PN junction, is changed depending on magnitude of the applied voltage, and thereby a capacitance value is changed, as well known; and when impurity concentration of a P-type region is different from that of an N-type region, the regions forming the PN junction, the thickness of depletion layers at a non-bias state is different from each other. Therefore, the capacitance value against applied voltage, or a characteristic of voltage against capacitance is also different depending on the impurity concentration.

Therefore, when processes to be used are different, the combinations of the variable capacitance element Cv and the fixed capacitance elements C_{MIM} in such a way that the slopes of the characteristics of control voltage to frequency are equalized in respective bands, and the intervals between respective bands are equalized are considered to be also different. Therefore, when the decoder is required to be in the same design independently of processes to be used, the codes for controlling the switch elements SWc2 to SWcn and SWv2 to SWvn are desirably prepared as the data table.

Specifically, even if the processes are different, in the case that the characteristic of the variable capacitance element Cv does not vary, when the variable capacitance element Cv is changed, the fixed capacitance element to be changed in a set with the element may be same, however, in the case that the characteristic of the variable capacitance element Cv varies for each process to be used, when the variable capacitance element Cv is changed, since the fixed capacitance element to be changed in a set with the element Cv also varies, a code for designating the fixed capacitance element that is combined with each of the variable capacitance elements or a decoder needs to be changed depending on the process.

For example, when the oscillator having the configuration as shown in FIG. 1 is assumed to be manufactured in a 0.18 μm process and a 0.25 μm process, which are used in a manufacturing line to which the inventors investigated use of the invention, calculation values of the capacitance value Cv of the varactor diode and the capacitance value C_{MIM} of the MIM capacitance element are shown in Table 1 and Table 2 respectively.

TABLE 1

| | VOC = 0 | VOC = 31 | VOC = 63 |
|---|---|---|---|
| Cv | 8,787 pF | 12.60 pF | 19.60 pF |
| C_{MIM} | 4.958 pF | 4.618 pF | 3.114 pF |
| | | | (0.18 μm process) |

TABLE 2

| | VOC = 0 | VOC = 31 | VOC = 63 |
|---|---|---|---|
| Cv | 7.678 pF | 11.01 pF | 17.12 pF |
| C_{MIM} | 6.033 pF | 6.159 pF | 5.511 pF |
| | | | (0.25 μm process) |

From Table 1 and Table 2, it is found that while the variation of capacitance of the varactor diode Cv is 10.813 pF in the 0.18 μm process, it is 9.442 pF in the 0.25 μm process. While the capacitance value of the varactor diode Cv is simply increased and the capacitance value of the MIM capacitance element C_{MIM} is simply decreased with changing in turn from the band VOC0 to the band VOC63 in Table 1 in the case of using the 0.18 μm process, the capacitance value of the varactor diode Cv is simply increased, while the capacitance value of the MIM capacitance element C_{MIM} is once increased and then decreased in Table 2 in the case of using the 0.25 μm process.

One reason why such a difference occurs is considered to be because even if only one varactor diode is provided, since the characteristic varies for each process, the number of fixed capacitance elements to be connected (magnitude of the capacitance value) varies, and when the number of connection of the fixed capacitance elements varies, a variation ratio of frequency also varies. From this, it is found that when the variable capacitance element Cv is changed, the fixed capacitance element to be connected in the set with the element Cv can not be uniquely determined independently of processes. The minimum capacitance value of the MIM capacitance element C_{MIM} is 3.114 pF in the case of using the 0.18 μm process, and the minimum value of the MIM capacitance element C_{MIM} is 5.511 pF in the case of using the 0.25 μm process.

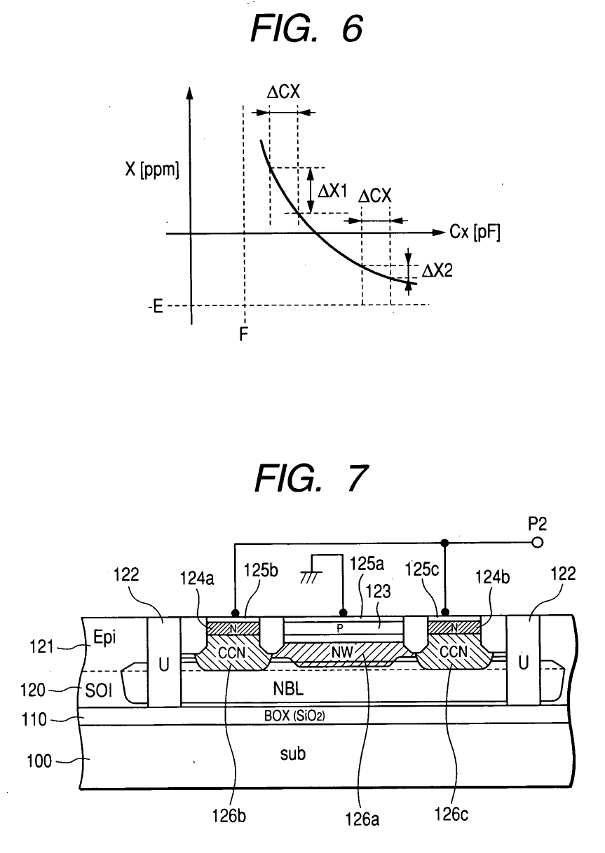

Here, a description is made on the reason why even if only one varactor diode is provided, when the number of connection of the fixed capacitance elements varies, the variation ratio of frequency also varies. As described before, in the oscillator of the embodiment, when it is required to be oscillated at X [ppm], the total capacitance Cx of the variable capacitance elements Cv1 to Cvn and the fixed capacitance elements C_{MIM1} to C_{MIMn} is expressed as the equation (8). By changing the equation, X=D/(Cx−F)−E is given. Since the D, E, and F are constants determined depending on circuits, when a relation between X and Cx is diagrammatically represented, an inverse proportion curve including Cx=F and X=−E as asymptotic lines is given as shown in FIG. 6. In FIG. 6, when a case that Cx varies only by the same amount ΔCx in each of cases of small total capacitance Cx and large total capacitance Cx by voltage applied to the variable capacitance element Cv is considered, since a slope of a curve is different at each position, a variation ΔX1 of frequency in the case of small total-capacitance Cx is found to be larger than a variation ΔX2 in frequency in the case of large total-capacitance Cx.

Next, for example, a designed value in the case of using the 0.25 μm process is given. A quartz resonator having the capacitance C1 of 6.9 fF, capacitance C0 of 1.7 pF, inductance L1 of 2.4911 mH, and resistance R1 of 10 Ω in the equivalent circuit shown in FIG. 2 is assumed to be used. A variation α of capacitance value at the control voltage of the varactor diode V_{AFC}=0.1 V is 0.961, and a variation βat the V_{AFC}=2.3 V is 0.601.

In the case of this condition, the inherent frequency fs of the quartz resonator is 38,388399 MHz according to fs=2π√(L1·C1). Since the capacitance value of the varactor diode in the case of VOC31 is 11.01 pF as shown in Table 2, the capacitance value Cv at V_{AFC}=0.1 V is 10.58 pF according to Cv=α×11.01=0.961×11.01; the synthesized capacitance CL is 10.41 pF according to CL=1/{(1/C3)+(1/C4)+(1/Cx)}; and the oscillation frequency f is 38.399335 MHz according to the equation (1). The capacitance value Cv at V_{AFC}=2.3 V is 6.62 pF according to Cv=β×11.01=0.601×11.01; the synthesized capacitance CL is 8.72 pF according to CL=1/{(1/C3)+(1/C4)+(1/Cx)}; and the oscillation frequency f is 38.401109 MHz according to the equation (1). Accordingly, the center frequency f_{center} is 38.400222 MHZ according to f_{center}=(38,399335+38.401109)÷2; and when V_{AFC} is changed from 0.1 V to 2.3 V, the variable range Δf of frequency is 46.2 [ppm] or ±23.1 [ppm] according to Δf=(38.399335−38.401109)÷f_{center}, which shows that the aforementioned requirements are satisfied.

FIG. 7 shows an example of a structure of the varactor diode suitable for the variable capacitance element for use in the voltage controlled oscillator (VCO) of the embodiment. In FIG. 7, a sign 100 is a semiconductor substrate such as single crystal silicon substrate; a sign 110 is an insulating film comprising silicon oxide formed on a surface of the substrate 100; a sign 120 is a semiconductor layer comprising single crystal silicon provided on the insulating film 110; and the substrate as a whole is formed as a SOI (Silicon On Insulator) structure.

An epitaxial layer 121 is formed on a surface of the semiconductor layer 120, and an island region, which is electrically isolated from the periphery by so-called U-trench isolation regions 122 formed by making a trench from a surface of the epitaxial layer and filling an insulating material into the trench, is formed. An N-type buried layer NBL is formed on a bottom of the island region, and a P-type anode region 123 configuring the varactor diode is formed thereon, and N-type cathode regions 124a, 124b are formed at both sides of the anode region 123.

While not particularly limited, contact layers 125a to 125c are provided on surfaces of the P-type anode region 123 and the N-type cathode regions 124a, 124b, and N-type buffer layers 126a to 126c are provided between the anode region 123 as well as the N-type cathode regions 124a, 124b and the buried layer NBL. It will be easily understood that in the varactor diode having such a structure, for example, if impurity concentration of the P-type anode region 123 varies, thickness of the depletion layer is shifted from the designed value, and thereby a characteristic of applied voltage to capacitance varies.

Next, a high frequency IC using the voltage controlled oscillator (VCO) of the embodiment as the reference signal generation source is described, in addition, an example of a configuration of an overall wireless communication system using the oscillator is described.

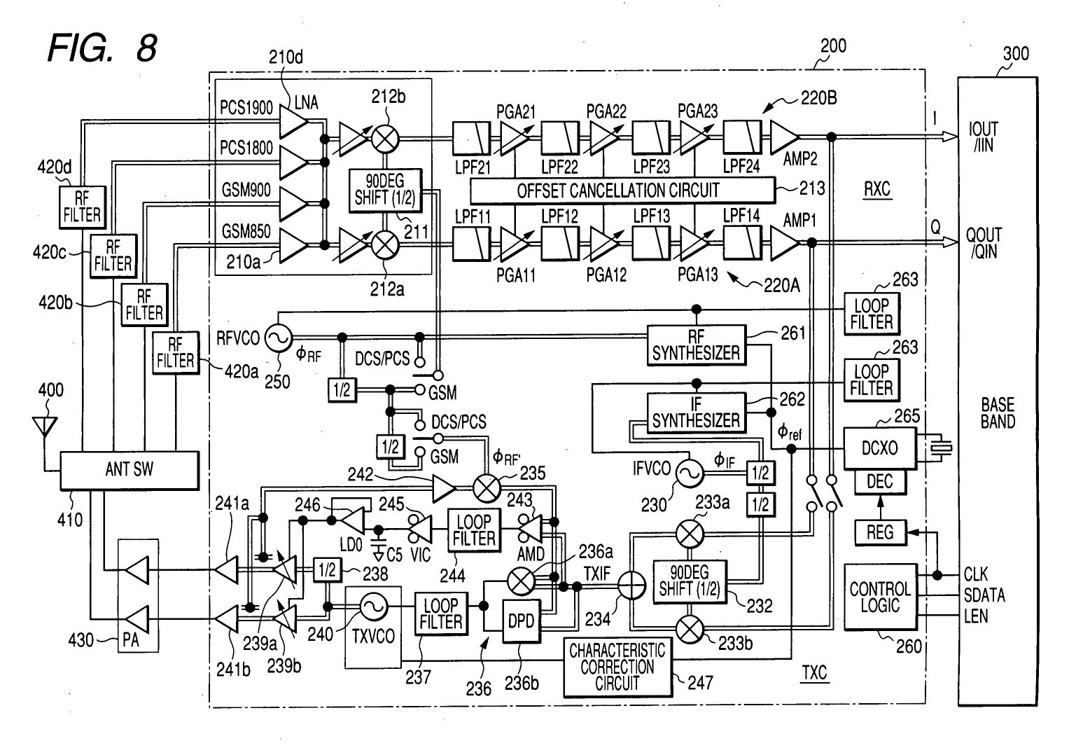

As shown in FIG. 8, the wireless communication system of the embodiment comprises an antenna 400 for transmitting/receiving a signal wave; a switch 410 for switching between transmission and reception; bandpass filters 420a to 420d comprising a SAW filter for removing unnecessary wave from a reception signal; a high-frequency power amplification circuit (power module) 430 for amplifying a transmission signal; a high frequency IC 200 for demodulating the reception signal and modulating the transmission signal and a baseband circuit 300 for converting transmitted data into an I or Q signal and controlling the high frequency IC 200. In the embodiment, the high frequency IC 200 and the baseband circuit 300 are formed as semiconductor integrated circuits on separate semiconductor chips, respectively.

While not particularly limited, the high frequency IC 200 of the embodiment is configured in a way that it can perform modulation/demodulation of signals in four frequency bands according to communication methods of GSM850, GSM900, DCS1800, and PCS1900. Correspondingly, as the bandpass filters, the filter 420a for allowing a reception signal at a frequency band of GSM850 to pass therethrough, the filter 420b for allowing a reception signal at a frequency band of GSM900 to pass therethrough, the filter 420c for allowing a reception signal at a frequency band of DCS1800 to pass therethrough, and the filter 420d for allowing a reception signal at a frequency band of PCS1900 to pass therethrough are provided.

When the high frequency IC 200 of the embodiment is roughly divided, it comprises a reception system circuit RXC, a transmission system circuit TXC, and a control system circuit comprising circuits common to the transmission and reception systems including a control circuit or clock generation circuit other than the system circuits.

The reception system circuit RXC comprises low-noise amplifiers 210a to 210d for amplifying reception signals at respective frequency bands of GSM850, GSM900, DCS1800, and PCS1900 respectively; a dividing/phase shift circuit 211 that divides a local oscillation signal φRF generated in the radio frequency oscillator (RFVCO) 250 and generates quadrature signals which are 90 deg. out of phase with each other; mixer circuits 212a, 212b that perform demodulation and down conversion of the I signal and the Q signal by mixing the reception signal amplified by the low-noise amplifiers 210a to 210d with the quadrature signals generated by the dividing/phase shift circuit 211; high gain amplification parts 220A, 220B common to respective frequency bands, which amplify the demodulated I and Q signals and output them to the baseband LSI 300 respectively; and an offset cancellation circuit 213 for canceling input DC offset voltage of amplifiers in the high gain amplification parts 220A, 220B.

The high gain amplification part 220A has a configuration where a plurality of low-pass filters LPF11, LPF12, LPF13, and LPF14 and gain control amplifiers PGA11, PGA12, and PGA13 are connected alternately in a series mode, and an amplifier AMP1 is connected to a final stage; and amplifies the demodulated I signal to a predetermined amplification level with removing unnecessary waves. Similarly, the high gain amplification part 220B has a configuration where a plurality of low-pass filters LPF21, LPF22, LPF23, and LPF24 and gain control amplifiers PGA21, PGA22, and PGA23 are connected alternately in a series mode, and an amplifier AMP2 is connected to a final stage; and amplifies the demodulated Q signal to a predetermined amplification level.

The offset cancellation circuit 213 comprises A/D conversion circuits (ADC) that are provided corresponding to respective gain control amplifiers PGA11 to PGA23 and converts differences in output potential of the amplifiers into digital signals with input terminals being shorted, D/A conversion circuits (DAC) that generate input offset voltage based on the conversion results of the A/D conversion circuits such that DC offset voltage of output of corresponding gain control amplifiers PGA11 to PGA23 becomes “0” and provide the input offset voltage to differential input; and a control circuit that controls the A/D conversion circuits (ADC) and the D/A conversion circuits (DAC) so that they perform offset cancellation operation.

The transmission system circuit TXC comprises an oscillator (IFVCO) 230 that generates an intermediate-frequency oscillation signal φIF such as 640 MHz; a dividing/phase shift circuit 232 that divides the oscillation signal φIF generated in the oscillator 230 and generates quadrature signals which are 90 deg. out of phase with each other; quadrature modulation circuits 233a, 233b that modulate the generated quadrature signals using the I signal and the Q signal supplied from the baseband circuit 300; an adder 234 that synthesizes the modulated signals; a transmission oscillator (TXVCO) 240 that generates a transmission signal φTX having a predetermined frequency; an offset mixer 235 that synthesizes a feedback signal sampled from the transmission signal φTX outputted from the transmission oscillator 240 using a coupler, and a signal φRF′ that is a dividing signal of the oscillation signal φRF generated by the radio frequency oscillator (RFVCO) 250, thereby generates a signal having a frequency corresponding to a difference in frequency of the signals; a phase comparison circuit 236 that compares output of the offset mixer 235 to the signal TXIF synthesized in the adder 234 to detect a frequency difference and a phase difference; a loop filter 237 that generates voltage corresponding to output of the phase comparison circuit 236; a frequency divider 238 that divides output of the TXVCO 240 and thus generates a GSM-based transmission signal; variable gain amplifiers 239a, 239b that amplify the signal divided by the frequency divider 238 and an output signal of the TXVCO 240 respectively; and buffer circuits 241a, 241b that convert differential output into a single signal and output the signal. One of the buffer circuits 241a, 241b is a circuit that outputs a signal in a band of 850 to 900 MHz for GSM, and the other is a circuit that outputs a signal in a band of 1800 to 1900 MHz for DCS and PCS.

Furthermore, the transmission system circuit TXC has an amplitude control loop comprising a buffer amplifier 242 that amplifies a feedback signal of output taken out from an output side of the variable gain amplifiers 239a, 239b and supplies the signal to an offset mixer 235; an amplitude comparison circuit 243 that compares the feedback signal amplified by the amplifier to the signal TXIF synthesized by the adder 234 to detect a difference in amplitude; a loop filter 244 that performs band limiting of output of the amplitude comparison circuit 243; a voltage/current conversion circuit 245 that converts voltage of the amplitude control loop into current; a capacitance element C5 for converting current into voltage; and a voltage follower 246 that performs impedance conversion of charge voltage of the capacitance element C5, and generates control voltage for variable gain amplifiers 239a, 239b at a latter stage of the TXVC 240. Thus, the circuit TXC is configured such that it can meet an EDGE mode for amplitude modulation and phase modulation.

While not particularly limited, the embodiment is configured in a way that an analog phase comparison circuit 236a having high accuracy and a digital phase comparison circuit 236b having high operation speed are provided in parallel for a phase comparison circuit 236 of PLL in the transmission system, and the high speed, digital phase comparison circuit is operated in an initial stage of operation, and switched to the highly accurate, analog phase comparison circuit after substantial matching of phases. By configuring in this way, locking at start of operation of the PLL circuit can be speeded up and improved in accuracy.

Furthermore, a control circuit 260 that generally controls the chip; an RF synthesizer 261 and a loop filter 263 that configure an RF PLL circuit with the radio frequency oscillator (RFVCO) 250; an IF synthesizer 262 and a loop filter 264 that configure an IF PLL circuit with the intermediate frequency oscillator (IFVCO) 230; a reference oscillator (DCXO) 265 that generates a reference signal φref for the synthesizers 261 and 262; and a characteristic correction circuit 247 for calibration of the transmission oscillator are provided on the chip of the high frequency IC 200 of the embodiment. While not shown, the synthesizers 261 and 262 comprise variable dividing circuits that divide oscillation signals of the VCO 250, 230, phase comparison circuits, charge pumps, and the like, respectively.

Since the reference oscillation signal φref is required to have high frequency accuracy, the reference oscillator 265 is connected with an external quartz resonator. Frequency such as 26 MHz or 13 MHz is selected for the reference oscillation signal φref. This is because the quartz resonator having such frequency is a widely used component, which is easily and inexpensively available.

In the control circuit 260 of the high frequency IC of the embodiment, a clock signal CLK for synchronization, data signal SDATA, and load enable signal LEN as control signal are supplied from the baseband IC 300 to the high frequency IC 200, and when the load enable signal LEN is asserted to an effective level, the control circuit 260 sequentially loads the data signal SDATA transmitted from the baseband IC 300 in synchronization with the clock signal CLK and sets the signal into the control register, and then generates a control signal for each circuit within the IC according to the content set. While not particularly limited, the data signal SDATA is serially transmitted. The baseband IC 300 comprises a microprocessor and the like. The data signal SDATA includes a command provided from the baseband IC 300 to the high frequency IC 200. The register REG of the reference oscillator 265 is directly set with a control code from the baseband IC 300. Regarding the control circuit 260, in a sleepmode, source voltage is turned off and the circuit enters a low power consumption mode, however, the register REG of the reference oscillation circuit 265 is supplied with power during the mode to prevent the operation from being stopped.

In the multi-band type, wireless communication system of the invention, for example, according to an instruction from the baseband IC 300, the control circuit 260 changes the frequency φRF of the oscillation signal of the radio frequency oscillator 250 depending on a channel to be used during transmission/reception, and changes the frequency of the signal supplied to the offset mixer 235 depending on whether it is the GSM mode or the DCS/PCS mode, thereby switching of transmission frequency is performed.

On the other hand, oscillation frequency of the radio frequency oscillator (RFVCO) 250 is set to a different value for each of the reception mode and the transmission mode. The oscillation frequency f_{RF} of the radio frequency oscillator (RFVCO) 250 is, for example, set to 3616 to 3716 MHz in the case of GSM850, 3840 to 3980 MHz in the case of GSM900, 3610 to 3730 MHz in the case of DCS, and 3860 to 3980 MHz in the case of PCS in the transmission mode, and the oscillation frequency f_{RF} is divided in four in the case of GSM, and divided in two in the case of DCS and PCS, and then supplied to the mixer 235.

The offset mixer 235 outputs a signal corresponding to a difference (f_{RF}−f_{TX}) between the frequency of the oscillation signal φ_{RF} from the RFCVO 250 and the frequency of the transmission oscillation signal φ_{TX} from the transmission oscillator (TXCVO) 240, and the transmission PLL (TX-PLL) operates such that the frequency of the difference signal corresponds to the frequency of the modulation signal TXIF. In other words, TXVCO 240 is controlled such that it oscillates at a frequency corresponding to the difference (offset) between the frequency of the oscillation signal φRF from the RFVCO 250 (f_{RF}/4 in the case of GSM, and f_{RF}/2 in the case of DCS and PCS) and the frequency of the modulation signal TXIF.

The high frequency IC 200 of the embodiment can be configured as a module by externally adding a quartz resonator thereto and mounting it on a single insulating substrate such as ceramic substrate. Moreover, it can be configured as a module where the filters 420a to 420d are further mounted on the ceramic substrate on which the high frequency IC 200 and the quartz resonator have been mounted. In the specification, one that is configured such that it can be handled as if it is a single electronic component by mounting a plurality of semiconductor chips and discrete components on the insulating substrate such as ceramic substrate or a package having printed wiring lines applied on a surface or in inside thereof, and then coupling the chips and the components with one another by the printed wiring lines or bonding wires such that they act predetermined roles is referred to as module.

While the invention made by the inventor has been specifically described according to the embodiment hereinabove, the invention is not limited to them. For example, while the invention that was applied to the VCO comprising the bias circuit, excitation circuit, and capacitive load circuit was described in the embodiment, it can be applied to an LC resonance type oscillator formed by cross-linking bases/collectors (or gates/drains) of a pair of differential transistors, and connecting a pair of inductors and varactor diodes between collectors of the differential transistors.

While the case that the invention was applied to the reference oscillator for generating the reference signal for the high frequency IC configuring the wireless communication system was described in the embodiment, application of the invention is not limited to it, and the invention can be applied to the RFVCO that generates the local oscillation signal which is commonly used for the reception system circuit and the transmission system circuit or the TXVCO for transmission.

Furthermore, while the decoder circuit is used as the circuit that generates the signal for controlling the switch elements SWc2 to SWcn and SWv2 to SWvn which selectively connect the fixed capacitance elements and the variable capacitance elements according to the input control signal (setting value of the register) in the embodiment, a random logic circuit or ROM (Read Only Memory) may be used to configure the circuit.

Furthermore, the reference oscillation element is required to have high frequency accuracy, and therefore the external quartz resonator was connected in the embodiment, however, the reference oscillation element can be any oscillation element as long as it satisfies the accuracy to be required, and for example, a ceramic oscillator can be used.

While the invention mainly made by the inventor has been described on the case that it is applied to the high frequency IC used in the wireless communication system such as mobile phone, which is the application field as the background of the invention, the invention is not limited to it, and can be generally used for a high frequency IC for wireless LAN and other semiconductor integrated circuits having the VCO for generating the oscillation signal.

What is claimed is:

1. A semiconductor integrated circuit for communication comprising:
an oscillator which includes a plurality of fixed capacitance elements, switch elements connected to the fixed capacitance elements, a plurality of variable capacitance elements, and switch elements connected to the variable capacitance elements, and which is capable of oscillating at a frequency corresponding to a synthesized capacitance value of the fixed capacitance elements and the variable capacitance elements, which are selectively connected by the switch elements, and an oscillation element; and
a control circuit which receives an input control signal and generates a control signal for controlling the switch elements according to characteristics of the variable capacitance elements.

2. The semiconductor integrated circuit for communication according to claim 1, wherein the control circuit is a decoder circuit which generates the control signal such that the input control signal and the control signal are in a predetermined relation according to characteristics of the fixed capacitance elements and the characteristic of the variable capacitance elements.

3. The semiconductor integrated circuit for communication according to claim 1, wherein the switch elements connected to the fixed capacitance elements are not connected to the variable capacitance elements, and the switch elements connected to the variable capacitance elements are not connected to the fixed capacitance elements.

4. The semiconductor integrated circuit for communication according to claim 1, comprising:
a demodulation circuit for demodulating a reception signal; and
a high frequency signal generation circuit for generating a high frequency signal used for demodulation in the demodulation circuit,
wherein an oscillation signal generated in the oscillator is supplied to the high frequency signal generation circuit as a reference signal.

5. The semiconductor integrated circuit for communication according to claim 4, further comprising:
a modulation circuit for modulating a transmission signal; and
a signal generation circuit for generating an intermediate frequency signal used for modulation in the modulation circuit,
wherein the oscillation signal generated in the oscillator is supplied to the signal generation circuit as the reference signal.

6. The semiconductor integrated circuit for communication according to claim 1, wherein the control circuit generates the signal for controlling the switch elements such that a combination of the variable capacitance element and the fixed capacitance element can be selected, in which slopes of characteristics of control voltage to frequency are equalized and intervals between respective characteristic lines are equalized, by the synthesized capacitance value of the fixed capacitance elements and the variable capacitance elements and the oscillation element.

7. The semiconductor integrated circuit for communication according to claim 1, wherein the oscillation element is formed with a monolithic element.

8. A communication system comprising:
the semiconductor integrated circuit for communication according to claim 7;
a semiconductor integrated circuit for control which supplies the input control signal; and
a memory unit for storing control data determined based on the characteristics of the fixed capacitance elements and the characteristics of the variable capacitance elements is provided in the semiconductor integrated circuit for control,
wherein the input control signal is generated based on the control data read out from the memory unit and supplied to the control circuit of the semiconductor integrated circuit for communication.

9. The communication system according to claim 8, wherein the control voltage for the variable capacitance elements is supplied from the semiconductor integrated circuit for control.

10. A method for manufacturing a semiconductor integrated circuit for communication comprising:
an oscillator which includes a plurality of fixed capacitance elements, switch elements connected to the fixed capacitance elements, a plurality of variable capacitance elements, and switch elements connected to the variable capacitance elements, and is capable of oscillating at a frequency corresponding to a synthesized capacitance value of the fixed capacitance elements and the variable capacitance elements, which are selectively connected by the switch elements, and an oscillation element; and
a control circuit which receives an input control signal and generates a control signal for controlling the switch elements according to characteristics of the variable capacitance elements,
wherein data for determining the control signal are obtained based on characteristics of the fixed capacitance elements and characteristics of the variable capacitance elements, logic of the control circuit is designed based on the data, and the control circuit is formed on a semiconductor substrate based on the designed value.
